(19) United States
(12) Patent Application Publication
(10) Pub. No.: US 2026/0180288 A1
(43) Pub. Date: Jun. 25, 2026

(54) QUANTUM CASCADE LASER WITH MODE SHAPING WAVEGUIDE COUPLER

(71) Applicant: IRGLARE, LLC, ORLANDO, FL (US)

(72) Inventor: Luke Milbocker, Oviedo, FL (US)

(21) Appl. No.: 19/423,266

(22) Filed: Dec. 17, 2025

Related U.S. Application Data
(60) Provisional application No. 63/738,108, filed on Dec. 23, 2024.

(51) Int. Cl. H01S 5/34; H01S 5/026; H01S 5/10

(52) U.S. Cl. CPC H01S 5/3402; H01S 5/026; H01S 5/1014

(57) ABSTRACT

A quantum cascade laser has an input waveguide that propagates a transverse optical mode of electromagnetic radiation generated by the QCL, a multimode interference (MMI) coupler, and an output waveguide. The coupler has (a) an input end that receives the transverse optical mode from the input waveguide, (b) a tapered section that modifies a transverse width of the transverse optical mode, and (c) an output end that outputs a modified-width transverse optical mode to the output waveguide. Modifying the transverse width of the transverse optical mode permits the input waveguide to have a different width than the output waveguide.

### CROSS-REFERENCE TO RELATED APPLICATION

This claims the benefit of priority to provisional Application No. 63/738,108, filed Dec. 23, 2024, which is incorporated by reference in its entirety.

### FIELD

This relates to the field of quantum cascade lasers and, more particularly, to quantum cascade lasers with waveguide couplers.

### BACKGROUND

A quantum cascade laser (“QCL”) is a semiconductor laser that uses intersubband radiative electron transitions between quantized energy levels to generate photons of radiation. QCLs have a laser core or gain region composed of multiple semiconductor layers with alternating band gap values grown by molecular beam epitaxy or metal organic chemical vapor deposition techniques. QCLs offer high optical power, small size, and potentially low cost in the mid and long wave infrared spectrum.

QCLs generate light through optical transitions of electrons between energy levels in the conduction band of quantum wells in the laser core when an electric field is applied. By tailoring the dimensions of the quantum wells, the emission wavelength can be tuned from mid-wave infrared (MWIR) to long-wave infrared (LWIR) spectral regions.

The light generated in the laser core is confined in a waveguide structure formed in the semiconductor. Conventional QCLs contain a single waveguide that is several millimeters in length and several microns wide. A monolithic QCL array contains multiple waveguides on a single semiconductor chip. The multiple waveguides may be physically connected and/or optically coupled by waveguide couplers.

### BRIEF SUMMARY

The problem with conventional QCL arrays is that conventional QCL waveguide couplers do not permit the input waveguides and output waveguides to have different widths. This problem is solved by using QCLs with waveguides couplers designed to modify the transverse width of the transverse optical mode between the input waveguide and output waveguide.

A first example of such a QCL includes an input ridge waveguide that propagates a transverse optical mode of electromagnetic radiation generated by the QCL. A multimode interference (MMI) coupler has an input end that receives the transverse optical mode from the input ridge waveguide, modifies a transverse width of the transverse optical mode, and outputs a modified-width transverse optical mode from an output end of the MMI coupler. An output ridge waveguide receives the modified-width transverse optical mode from the output end and propagates the modified-width transverse optical mode. The input ridge waveguide has a different ridge width than the output ridge waveguide.

The QCL may further include one or more of the following features.

The input ridge waveguide may have a larger ridge width than the output ridge waveguide and the MMI coupler may compress the transverse width of the transverse optical mode.

The input ridge waveguide may have a smaller ridge width than the output ridge waveguide and the MMI coupler may expand the transverse width of the transverse optical mode.

The MMI coupler may include a tapered ridge width between the input end and the output end and the tapered ridge width modifies the transverse width of the transverse optical mode.

The QCL may be a tree array QCL and the MMI coupler receives the transverse optical mode from more than one input ridge waveguide.

The input ridge waveguide, MMI coupler, and output ridge waveguide may together form a monolithic ridge.

The transverse optical mode may be TM₀₀ of the input ridge waveguide and the modified-width transverse optical mode may be TM₀₀ of the output ridge waveguide.

A second example of such a QCL includes an input waveguide that propagates a transverse optical mode of electromagnetic radiation generated by the QCL. A multimode interference (MMI) coupler has (a) an input end that receives the transverse optical mode from the input waveguide, (b) a tapered section that modifies a transverse width of the transverse optical mode, and (c) an output end that outputs a modified-width transverse optical mode. An output waveguide receives the modified-width transverse optical mode from the output end and propagates the modified-width transverse optical mode.

The QCL may further include one or more of the following features.

The input waveguide may have a larger ridge width than the output waveguide and the tapered section may compress the transverse width of the transverse optical mode.

The input waveguide may have a smaller ridge width than the output waveguide and the tapered section may expand the transverse width of the transverse optical mode.

The tapered section may have a tapered ridge width between the input end and the output end and the tapered ridge modifies the transverse width of the transverse optical mode.

The MMI coupler may reduce an optical intensity of the electromagnetic radiation in the output waveguide relative to the input waveguide.

The input waveguide, MMI coupler, and output waveguide may together form a monolithic ridge.

The transverse optical mode may be TM₀₀ of the input waveguide and the modified-width transverse optical mode may be TM₀₀ of the output waveguide.

An example of a tree array QCL includes a plurality of input waveguides that respectively propagate a transverse optical mode of electromagnetic radiation generated by the QCL. A multimode interference (MMI) coupler has (a) an input end that receives the transverse optical mode from the plurality of input waveguides, (b) a tapered section that modifies a transverse width of the transverse optical mode, and (c) an output end that outputs a modified-width transverse optical mode. A single output waveguide receives the modified-width transverse optical mode from the output end and propagates the modified-width transverse optical mode.

The tree array QCL may further include one or more of the following features.

The input waveguides may have a larger ridge width than the output waveguide and the tapered section may compress the transverse width of the transverse optical mode.

The input waveguides may have a smaller ridge width than the output waveguide and the tapered section may expand the transverse width of the transverse optical mode.

The tapered section may have a tapered ridge width between the input end and the output end and the tapered ridge width modifies the transverse width of the transverse optical mode.

The MMI coupler may reduce an optical intensity of the electromagnetic radiation in the output waveguide relative to the input waveguides by expanding the transverse width of the transverse optical mode.

The MMI coupler may reduce an ellipticity of the electromagnetic radiation emitted from the output waveguide relative to the input waveguides by compressing the transverse width of the transverse optical mode.

The input waveguides, MMI coupler, and output waveguide may together form a monolithic QCL with a continuous ridge forming the input waveguides, MMI coupler, and output waveguide.

The transverse optical mode may be TM₀₀ of the input waveguides and the modified-width transverse optical mode may be TM₀₀ of the output waveguide.

### BRIEF DESCRIPTION OF THE DRAWINGS

FIG. 1 is a schematic of a QCL showing the material layers from which an example of the QCL may be constructed.

FIG. 2 is a block diagram of an example of a QCL core layer.

FIG. 3 is a block diagram of a QCL with a mode shaping waveguide coupler.

FIG. 4 is a block diagram of a QCL with a mode shaping waveguide coupler in which the input waveguides have a smaller width than the output waveguide.

FIG. 5 is a block diagram of a QCL with a mode shaping waveguide coupler in which the input waveguides have a larger width than the output waveguide.

FIG. 6 is a block diagram of a QCL with a mode expanding waveguide coupler.

FIG. 7 is a block diagram of a QCL with a mode compressing waveguide coupler.

FIG. 8 is a finite element analysis (FEA) simulation showing the optical intensity in an exemplary mode expanding waveguide coupler with two input waveguides and one output waveguide.

FIG. 9 is a finite element analysis (FEA) simulation showing the optical intensity in an exemplary mode compressing waveguide coupler with two input waveguides and one output waveguide.

FIG. 10 is a top view of a tree array QCL

FIG. 11 is a perspective view of the tree array QCL of FIG. 10.

FIG. 12 is a schematic of a two layer tree array QCL.

### DETAILED DESCRIPTION

This disclosure describes examples and features, but not all possible examples and features of the QCL and related methods. Where a particular feature is disclosed in the context of a particular example, that feature can also be used, to the extent possible, in combination with and/or in the context of other features and examples. The QCL, its features, and related methods may be embodied in many different forms and should not be construed as limited to only the examples described here.

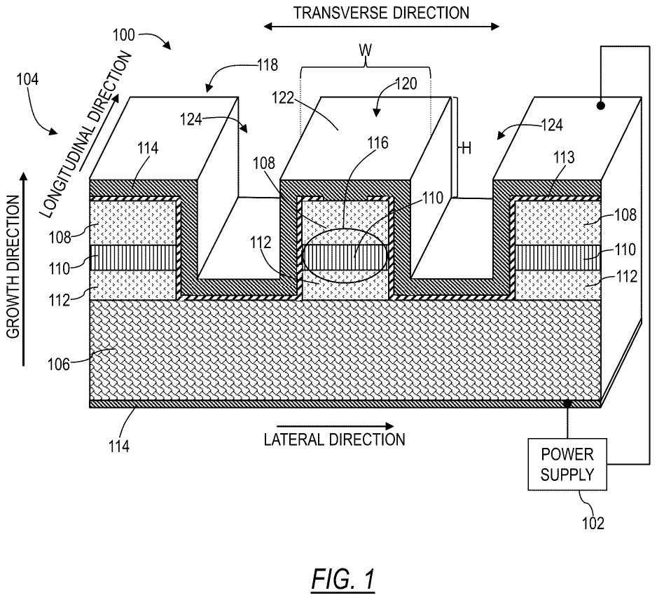

Referring to FIG. 1 an example of QCL 100 includes a power supply 102 and a QCL device 104. The power supply 102 provides electric power to operate the QCL device 104. The QCL device 104 includes a substrate 106, a top cladding layer 108, a QCL core layer 110, a bottom cladding layer 112, a dielectric material layer 113, an electrically conductive layer 114, an output facet 116, and a back facet 118.

The power supply 102 may be a conventional QCL power supply. A typically QCL power supply, for example, operates at currents up to 20 A and voltages up to 25 V. Although the power supplied to the QCL device 104 is design and wavelength dependent, it typically supplies 2 A and 15 V to the QCL device 104.

The QCL device 104 may operate in either pulse or continuous wave (CW) mode. Pulse widths of the QCL device 104 may be <1 μs or 300 ns to 600 ns, for example.

The substrate 106 is made from one or more semiconducting materials. Examples of semiconducting materials suitable for the substrate 106 include, but are not limited to, InP, GaAs, InAs, Si, or the like. Other semiconducting materials used in a substrate layer of a QCL may be used.

The top cladding layer 108 and bottom cladding layer 112 are made from one or more semiconducting materials. Examples of suitable semiconducting materials for the cladding layers 108, 112 include, but are not limited to InP, InGaAs, and the like. Other semiconducting materials used in a cladding layer of a QCL may be used.

The top cladding layer 108, bottom cladding layer 112, and substrate 106 may be composed of the same semiconducting material or different semiconducting materials.

The dielectric material layer 113 may be composed of one or more dielectric materials such as silicon nitride, silicon dioxide, or the like, for example. Other dielectric materials used in a dielectric material layer of a QCL may be used.

The dielectric material layer 113 provides electrical insulation between the electrically conductive layer 114 and the top cladding layer 108, QCL core layer 110, and bottom cladding layer 112.

The electrically conductive layer 114 is made of one or more conducting materials, such as metals or the like, that allow the QCL device 104 to receive electrical power from the power supply 102.

The output facet 116 is the portion of QCL device 104 that outputs the radiation. The QCL device 104 in FIG. 1 is an edge emitting QCL because the output facet 116 is positioned on the edge of the QCL device 104. The output facet 116 emits radiation non-parallel, often substantially perpendicular to the growth direction.

Together, the top cladding layer 108, QCL core layer 110, and bottom cladding layer 112 cooperate to form an optical waveguide that guides radiation generated by the QCL core layer 110 along the waveguide.

In this example, the optical waveguide is a ridge waveguide 120 formed in the QCL device 104. The ridge waveguide 120 extends longitudinally from the back facet 118 to the output facet 116. The back facet 118 is opposite the output facet 116 and is designed to reflect radiation from the ridge waveguide 120 back into the ridge waveguide 120. The back facet 118 may be coated with a highly reflective coating capable of reflecting the radiation. Examples of highly reflective coatings include, but are not limited to metallic coatings such as gold and the like and/or multi-layer dielectric materials such as ZnSe, Y₂O₃, and Al₂O₃ and the like.

The ridge waveguide 120 is defined by a longitudinally extending ridge 122 having a ridge width W and a height H. The ridge 122 is bordered on either lateral side thereof by channels 124. The channels 124 extend down through the top cladding layers 108, QCL core layer 110, and bottom cladding layer 112.

In certain examples of the QCL device 104, the ridge width W is >100 μm, 4 μm-30 μm, or 5 μm-20 μm. In certain examples, the height H is 3 μm-15 μm. These dimensions can also vary outside the specified ranges for some applications. The ridge width W can also vary along the length of the QCL device 104 as explained below to accommodate input waveguides, output waveguides, and waveguide couplers.

The channels 124 may be left empty or, if desired, be filled with a semi-insulating material such as InP or the like. Filling the channels 124 with a semi-insulating material would provide a buried heterostructure (BH) configuration.

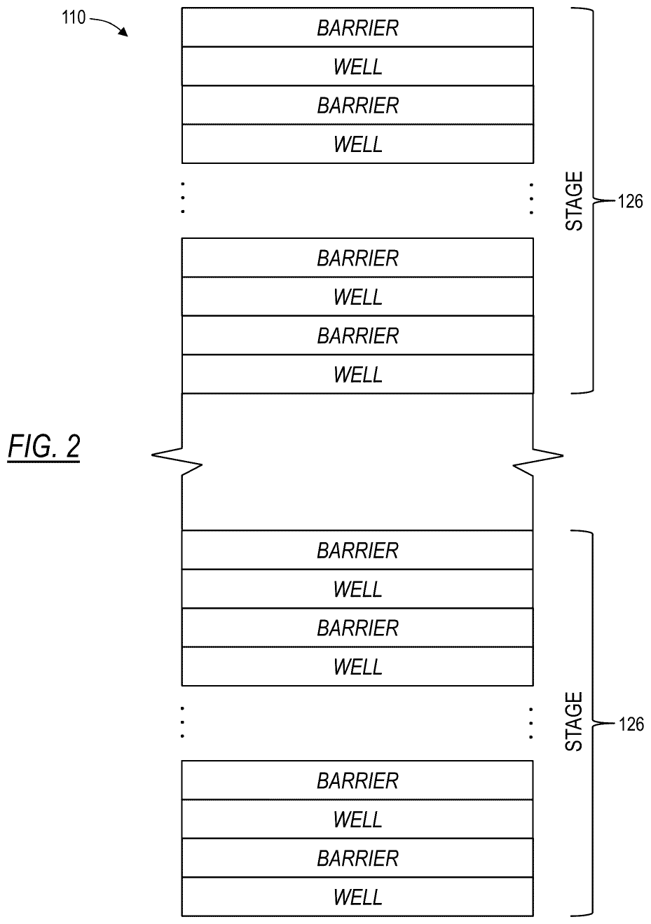

Referring to FIG. 2, details of the QCL core layer 110 are now described. The QCL core layer 110 is the laser gain region of the QCL, which generates photons via intersubband transitions. The QCL core layer 110 includes a plurality of stages 126 composed of optically interacting quantum wells and quantum barriers. When a voltage is applied across the QCL core layer 110, the stages 126 generate photons due to carrier excitation and relaxation between subbands. The number of stages 126 and thickness of stages 126 in the crystal growth direction can vary depending on the desired properties of the QCL device 104. The QCL core layer 110 is grown in the growth direction shown in FIG. 1 using a semiconductor growth technique such as molecular beam epitaxy, metal organic chemical vapor deposition, and/or the like.

The quantum wells may be made of one or more semiconducting materials. Examples of semiconducting materials suitable for the quantum wells include, but are not limited to, InGaAs, GaAs, InAs, and the like.

The quantum barriers may be made of one or more semiconducting materials. Examples of semiconducting materials suitable for the quantum barriers include, but are not limited to, AlInAs, AlAsSb, AlSb, and the like.

A typical example of a QCL core layer 110 has 30-50 stages 126 in which each stage 126 has a thickness of approximately 30 to 60 nm.

The QCL construction described above is just an example of possible ways the QCL may be constructed.

QCLs are generally described in Faist, J. (2013), Quantum Cascade Lasers. Oxford Scholarship Online. https://doi.org/10.1093/acprof:oso/9780198528241.001.0001, which is incorporated herein by reference in its entirety. In some cases, the laser structure is grown lattice matched to an InP, GaAs, or InAs substrate 106 by molecular beam epitaxy (MBE) or metalorganic chemical vapor deposition (MOCVD). Channels 124 may then be etched into the multilayer structure to create a ridge wave-guide with electrical and optical confinement. The etched channels 124 provide lateral waveguide confinement, while the multilayer semiconductor substrate provides vertical waveguide confinement around the core layer 110. The ridge waveguide 120 is typically several millimeters in length, and several microns wide. In some cases, the ridge waveguide is surrounded by regrown semiconductor to form a buried heterostructure (BH) waveguide. In either case, the wafer may be cleaved perpendicular to the ridge to form facets that act as mirrors of the laser. Coatings may be deposited on the facets to alter their reflectivity. Laser light is amplified by electrically pumping a ridge waveguide 120 while light bounces between the facet mirrors. Light is emitted from one or more facets due to their partial reflectivity.

Conventional QCLs contain a single waveguide that is several millimeters long and several microns wide. A monolithic QCL array contains multiple waveguides on a single semiconductor chip. The multiple waveguides may be physically connected and/or optically coupled by a waveguide coupler.

A waveguide coupler is a multimode interference coupler (MMI) waveguide with at least one input waveguide and at least one output waveguide. The waveguide coupler couples electromagnetic radiation generated by the QCL from the input waveguide(s) to the output waveguide(s), whereby optical power is transmitted from the input waveguide(s) to the output waveguide(s). Optical power may also be transmitted from the output waveguide(s) to the input waveguide(s).

QCL devices 104 with an advantageous mode expanding or mode compressing waveguide coupler are now described.

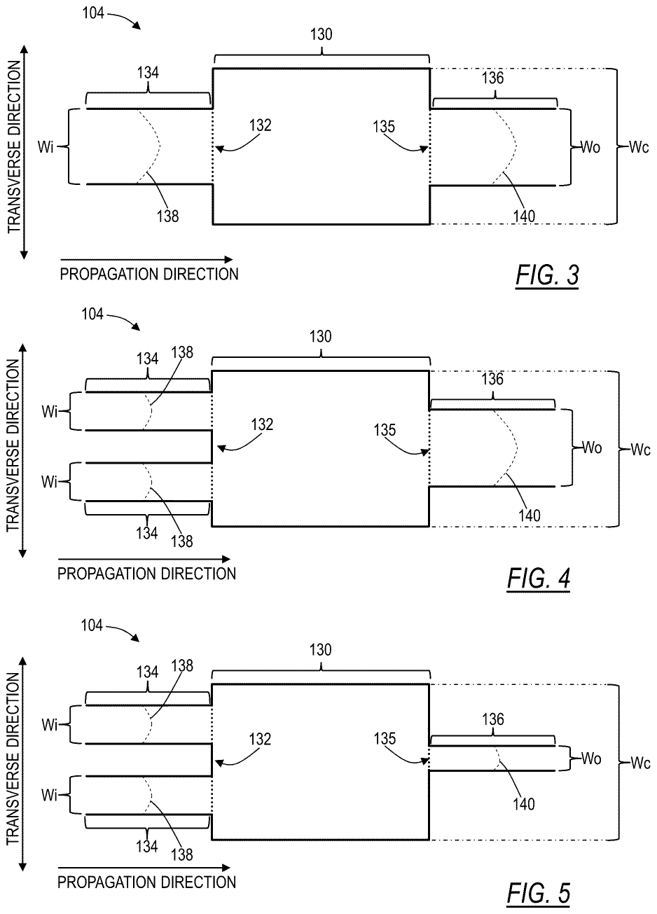

Referring to FIG. 3, such a QCL device 104 includes at least one input waveguide 134, a waveguide coupler 130, and at least one output waveguide 136. The waveguide coupler 130 includes an input end 132 coupled to the input waveguide 134 and an output end 135 coupled to the output waveguide 136. The waveguide coupler 130, input waveguide 134, and output waveguide 136 may be monolithically constructed as in FIG. 1, such that the waveguide coupler 130, input waveguide 134, and output waveguide 136 form a continuous ridge 122 on the same wafer.

The input waveguide 134 may be a ridge waveguide with ridge width Wi. The input waveguide 134 propagates a transverse optical mode 138 of the radiation generated by the QCL, which is represented by the dashed line, longitudinally along the propagation direction. The input waveguide 134 outputs the transverse optical mode 138 to the waveguide coupler 130 at the input end 132. The input end 132 is the junction between the input waveguide 134 and the waveguide coupler 130.

The waveguide coupler 130 may be a ridge waveguide with ridge width Wc and is configured to modify the width of the transverse optical mode in the transverse direction and output a modified-width transverse optical mode of the radiation from the output end 135 to the output waveguide 136. The output end 135 is the junction between the waveguide coupler 130 and the output waveguide 136.

The output waveguide 136 receives the modified-width transverse optical mode 140 from the waveguide coupler 130 and propagates the modified-width transverse optical mode 140 along the propagation direction. In some examples, the output waveguide 136 terminates at the output facet 116 from which the QCL beam is emitted. In other examples, the output waveguide 136 functions as an input waveguide 134 to another waveguide coupler 130 downstream, such as in a tree array QCL.

A transverse optical mode of a waveguide is a stable standing wave pattern of the radiation's electric and magnetic field components in the transverse plane, which is perpendicular to the propagation direction of the waveguide. The input waveguide 134 and output waveguide 136 are typically configured such that the fundamental mode TM₀₀ is the primary mode each waveguide propagates; however, they can be modified to propagate other modes. The primary mode a waveguide propagates is a function of the dimensions of the waveguide relative to the wavelength of the radiation being propagated.

The waveguide coupler 130 is configured to couple input waveguides 134 and output waveguides 136 of different ridge widths Wi and Wc by expanding or compressing the transverse width of the transverse optical mode 138 in the input waveguide 134 and outputting the modified-width transverse optical mode 140 to the output waveguide 136. This mode-shaping waveguide coupler 130 may be used, for example, in various QCL array architectures to improve performance for various applications.

In some case, it is desirable to increase the transverse width of the transverse optical mode to decrease the optical intensity in the output waveguide 136. This is useful in high power laser arrays that are susceptible to catastrophic optical damage (COD). COD occurs when the optical intensity in the laser reaches the threshold for internal damage. By increasing the width of the transverse optical mode thereby spreading the transverse optical mode over a larger area, the optical intensity decreases and the laser can emit more power before risking COD.

This is especially useful for tree array QCLs. A tree array QCL is a monolithic array of QCL waveguides with a branching structure where the input waveguides 134 are called branch waveguides and the output waveguides 136 are called stem waveguides. The branch waveguides and stem waveguides are interconnected with one or more waveguide couplers 130. In a tree array QCL, power from multiple branch waveguides is combined into a single stem waveguide, creating a region with high optical intensity.

One way that COD has been mitigated in tree array QCLs previously by emitting the optical power from the branches-side facet of the tree array, thereby dividing the optical intensity among several emitting branch waveguides and reducing the risk of COD. Zhou, W., Lu, Q.-Y., Wu, D.-H., Slivken, S., & Razeghi, M. (2019). High-power, continuous-wave, phase-locked quantum cascade laser arrays emitting at 8 μm. Optics Express, 27(11), 15776. https://doi.org/10.1364/oe.27.015776. This approach is not ideal for high brightness applications because it requires additional beam combining optics to combine the beams emitted from multiple disparate branch waveguides to achieve a high brightness laser beam.

Some examples of the waveguide coupler 130 can mitigate COD in tree array QCLs configured to emit from a single stem waveguide for high brightness applications. Emitting single stem waveguide is advantageous because no external beam combining is needed to produce a high-brightness laser beam. Since tree array QCLs are currently being developed for high power and high brightness applications, the waveguide coupler 130 can significantly improve the performance and reliability of these arrays.

COD can be mitigated in conventional Fabry Perot cavity QCLs by tapering the width of the waveguide to be wider at the output facet. Lyakh, A., Maulini, R., Tsekoun, A., Go, R., & Patel, C. K. N. (2014). Continuous wave operation of buried heterostructure 4.6 μm quantum cascade laser Y-junctions and tree arrays. Optics Express, 22(1), 1203. https://doi.org/10.1364/oe.22.001203. This approach is not ideal for tree array QCLs for multiple reasons. First, the stem waveguide at the output facet of a tree array QCL is typically made as short as possible to maximize the length of the branch waveguides and to improve the efficiency of the laser. A short stem waveguide section would require a taper angle that is too large to support adiabatic propagation of the fundamental transverse optical mode, leading to high order mode excitation that deteriorates brightness. Second, while a tapered stem waveguide section reduces the optical intensity at the output facet, the stem waveguide is still narrow at the narrow side of the taper, leading to high optical intensity and increased risk of COD. The waveguide coupler 130 described here permits a wider stem waveguide to be used with reduced risk of COD.

Another advantage of a waveguide coupler 130 that changes the transverse optical mode size in QCL arrays is that curved waveguides, for example in S-bends of a tree array, can be narrower than the stem waveguide. In a tree array QCL without the waveguide coupler 130 described here, it is usually advantageous to use narrow waveguides in the S-bends adjacent to the waveguide coupler 130 to reduce excitations of high order modes at points where the waveguide's curvature changes along the bends.

Implementing narrow curved waveguides typically necessitates using either a narrow stem section, or tapered waveguides before or after the conventional waveguide coupler to increase the mode size after the bends. A narrow stem section is susceptible to COD, and the disadvantages of tapering the stem waveguide were summarized above. Likewise, tapering the waveguide(s) before the conventional waveguide coupler can be problematic. Tapering waveguides to be wider at the inputs of the conventional waveguide coupler forces the conventional waveguide coupler to have a larger footprint. In the case of conventional MMI couplers, the length is proportional to the width squared, so increasing the coupler width greatly increases its length and footprint. A longer conventional waveguide coupler increases optical losses if it is unpowered, or greatly increases current draw if powered.

Some examples of the waveguide coupler 130 described here increase the transverse width of the transverse optical mode, which allows narrow input waveguides 134 to be combined with a wide output waveguide 136, combining the benefits of narrow S-bend waveguides and wide stem waveguide with a reduced overall footprint of the waveguide coupler 130 relative to a conventional waveguide coupler.

Certain examples of the waveguide coupler 130 are able to change the transverse width of the transverse optical mode 138 to reduce the ellipticity of the laser beam emitted from laser. QCL waveguides are typically wider along the transverse direction than the vertical direction, which makes the emitted laser beam elliptical, diverging at different angles along the transverse and vertical axes, colloquially called the slow and fast axes. Highly elliptical laser beams require multiple lenses to collimate compared to a single lens for a circular laser beam. However, it may be desirable to use wide waveguides for power scaling, heat dissipation, or reducing optical losses in the waveguide. The waveguide coupler 130 describe herein may be used to reduce the ellipticity of the emitted laser beam in arrays where wide waveguides are used.

Another advantage of the waveguide coupler 130 is that changing the width of the transverse optical mode 138 can increase the fill factor of the emitted beam(s) in a QCL array with multiple emitter waveguides to improve beam combining. The fill factor can be increased by spacing the emitters closer together, or by increasing the width of the emitter waveguides. The lower limit of the emitter waveguide spacing is limited by heat generation in high power QCL arrays, so there is a need to increase the width of the emitter waveguides to improve the fill factor. In a QCL array, multiple waveguide couplers 130 that increase the size of the transverse optical mode can be positioned near the emitter waveguides to increase the fill factor of the emitted beams for external beam combining.

In some examples, the waveguide coupler 130 is a mode expanding coupler where the transverse optical mode 138 of the input waveguide(s) 134 is smaller in transverse width than the transverse optical mode 140 of the output waveguide(s) 136, where the output waveguide 136 is nearest to an output facet 116 of the laser. The transverse width Wc of a transverse optical mode expanding waveguide coupler 130 is narrower at the input end 132 than the output end 135.

In some examples, the waveguide coupler 130 is a mode focusing coupler where the transverse optical mode 138 of the input waveguide(s) 134 is larger in transverse width than the transverse optical mode 140 of the output waveguide(s) 136, where the output waveguide 136 is nearest to the output facet 116 of the laser. The transverse width of a mode focusing coupler is wider at the input end 132 than the output end 135.

Referring to FIG. 4, the waveguide coupler 130 couples two input waveguides 134, each having input waveguide ridge width Wi, to a single output waveguide 136 having output waveguide ridge width Wo In this example Wi<Wo, therefore, the waveguide coupler 130 expands the transverse width of the transverse optical mode 138 propagated by the input waveguides 134.

Referring to FIG. 5, the waveguide coupler 130 couples two input waveguides 134, each having input waveguide ridge width Wi, to a single output waveguide 136 having output waveguide ridge width Wo. In this example Wi>Wo, therefore, the waveguide coupler 130 compresses the transverse width of the transverse optical mode 138 propagated by the input waveguides 134.

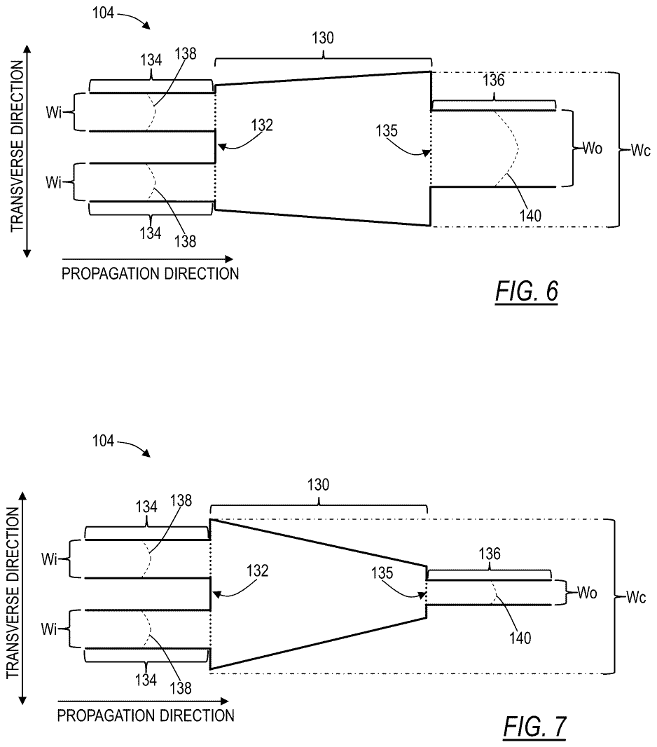

One technique for modifying the transverse width of the transverse optical mode 138 is to taper the ridge width Wc of the waveguide coupler 130 between the input end 132 and the output end 135 as shown in FIGS. 6 and 7 in the longitudinal or propagation direction. In FIG. 6, the waveguide coupler 130 is a mode expanding coupler in which Wi<Wo and the ridge width Wc of the waveguide coupler 130 increases linearly between the input end 132 and the output end 135. In FIG. 7, the waveguide coupler 130 is a mode compressing coupler in which Wi>Wo and the ridge width Wc of the waveguide coupler 130 decreases linearly between the input end 132 and the output end 135.

The taper of the waveguide coupler 130 need not be linear in every example. The taper may, for example, be parabolic or nonuniform with the proviso that the average ridge width Wc of one half of the waveguide coupler 130 is larger than the average ridge width Wc of the other half of the waveguide coupler 130.

For a linearly tapered waveguide coupler 130, the ratio of the input waveguide ridge width Wi to the output waveguide ridge width Wo is about the same as the ratio of the waveguide coupler ridge width Wc at the input end 132 and the output end 135.

For a conventional (1 input and N outputs) waveguide coupler that is not tapered and not mode shaping, the longitudinal length of the waveguide coupler is related to the ridge width by L=(nW²)/Nλ where n is the refractive index, λ is the wavelength, and W is the effective width, which depends also on the mode penetration into the surrounding waveguide cladding. For a tapered mode shaping waveguide coupler 130, this relation holds where W is the average ridge width Wc instead of a constant ridge width.

As an example, if the wavelength range of the QCL 3 μm-12 μm and the refractive index n is between 3 and 3.5. The ridge width Wc must be large enough to accommodate the input waveguide(s) 134 and output waveguide(s) 136. If there are two output waveguides 136 that are each 5 μm wide, the waveguide coupler 130 ridge width Wc is at least 10 μm on the output end 135. The input waveguide ridge width Wi and the output waveguide ridge width Wo are wavelength dependent, but are often in the range 4 μm-25 μm. In most cases, the input waveguide(s) 134 and output waveguide(s) 136 are operating at the fundamental transverse optical mode TM₀₀. At their respective junctions with the waveguide coupler 130, multiple higher order modes are excited, so the fundamental transverse optical mode couples to multiple higher order modes in these regions which is why the waveguide coupler 130 is considered an MMI coupler.

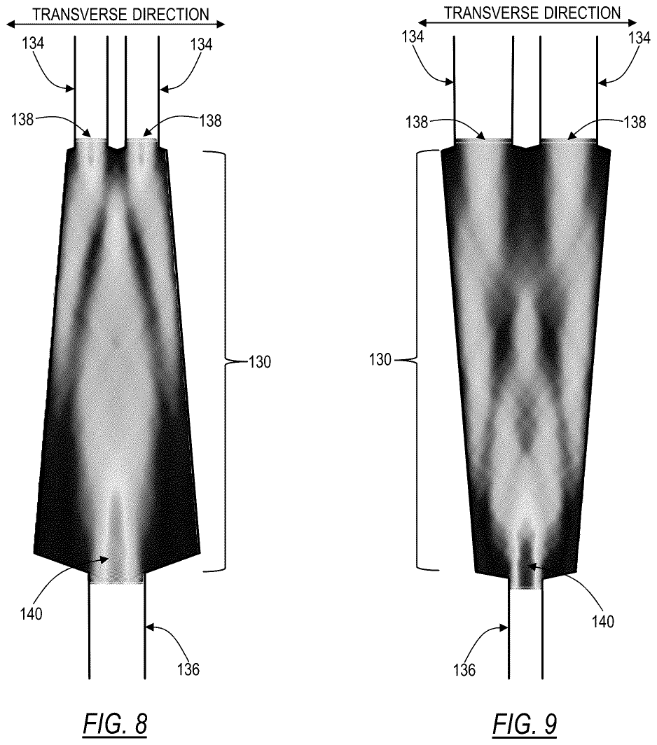

FIGS. 8 and 9 are finite element analysis (FEA) simulations showing the optical intensity inside an exemplary waveguide coupler 130 with two input waveguides 134 and one output waveguide 136. FIG. 8 shows a mode expanding coupler (Wi<Wo). From the optical intensity, it is apparent that the waveguide coupler 130 expands the transverse width of the TM₀₀ mode. FIG. 9 shows a mode compressing coupler (Wi>Wo). From the optical intensity, it is apparent that the waveguide coupler 130 compresses the transverse width of the TM₀₀ mode.

The waveguide coupler 130 has many uses as discussed above. One of its particularly advantageous uses is in a QCL array such as a tree array QCL.

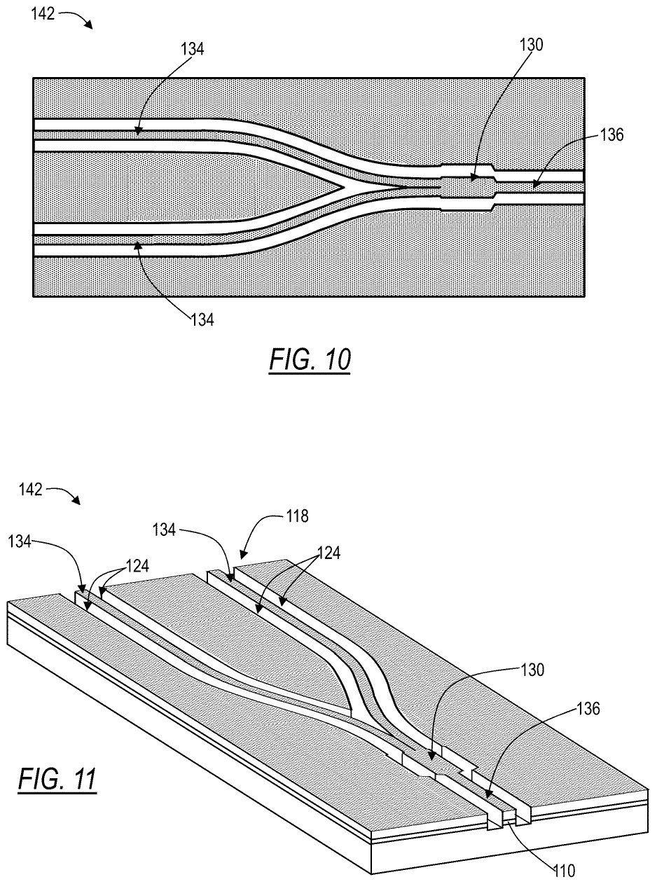

One example of a basic tree array QCL has a plurality of branch waveguides and a single stem waveguide from which the laser beam is emitted. This configuration is advantageous for high brightness applications because the radiation is concentrated into a single beam. Referring to FIGS. 10 and 11, an example of such a tree array QCL 142 includes a waveguide coupler 130 coupling two input waveguides 134 (branch waveguides) to a single output waveguide 136 (stem waveguide). Some of the QCL array waveguides may be isolated from electrical current to remain unpowered during operation. The tree array QCL 142 is constructed as in FIG. 1.

A method of fabricating a particular example of a tree array QCL 142 is now described. The tree array QCL 142 is prepared by etching the monolithic waveguide structure into a semiconductor wafer. An example of the semiconductor wafer has the following layer sequence: n InP substrate lower cladding, InGaAs/AlInAs core layer layers, n InP upper cladding, n+InGaAs contact layer.

Ridge waveguides are formed by etching channels to a depth below the core layer. They may be covered with a dielectric layer and a metal layer, with an opening in the dielectric layer on top of the ridge for current conduction between the ridge and metal layers. The dielectric layer may be, but is not limited to, SiO₂ or Si₃N₄. The top metal may be, but is not limited to, Ti/Au. For instance, 350 nm of Si₃N₄ and 10 nm Ti/3 μm of Au may be used as the dielectric layer and top metal, respectively. The wafer may be thinned and polished from the backside. A bottom metal contact may be deposited on the back of the wafer below the n InP lower cladding. The bottom contact may be, but is not limited to, Ni/Ge/Au.

The total length of a tree array QCL 142 is typically in the range 2-12 mm. If ridge waveguides are used, the width is typically at least 6 μm to minimize optical scattering losses for efficient operation. The width of the ridge waveguides may vary continuously at any point, or different waveguide sections may have different widths.

A tree array QCL 142 may have any number of branch waveguides and any number of waveguide couplers 130. Further, a waveguide coupler 130 may combine light from any number of input waveguides 134. For instance, a waveguide coupler 130 may be an N×1 device receiving radiation from N inputs and providing the radiation to a single output waveguide 136, where N is any integer greater than one. In this way, the waveguide coupler 130 forms a tree structure with any number of layers.

As an illustration, a tree array QCL 142 may include a single waveguide coupler 130 to simultaneously combine light from any number of branch input waveguides 134 through any number of curved waveguide regions. Such a configuration corresponds to a 1-layer tree structure as in FIGS. 10 and 11.

As another illustration, a tree array QCL 142 include multiple layers of waveguide couplers 130. For example, a QCL with four branch input waveguides 134 may include two 2×1 waveguide couplers 130 in a first layer and one 2×1 waveguide couplers 130 in a second layer to progressively combine light into a single emitter output waveguide 136 region.

In a tree array QCL, when the waveguide coupler 130 is a mode expanding coupler (Wi<Wo), the transverse optical modes 138 of the input (branch) waveguides 134 have a smaller transverse width than the transverse optical mode 140 at the output (stem) waveguides 136. The increase in transverse optical mode width reduces the optical intensity in the output waveguides 136 compared to an equivalent tree array QCL without the mode shaping waveguide coupler 130. This decrease in optical intensity reduces the risk of COD, increasing the potential output power of the laser. This is useful because output power can be scaled in tree arrays with the number of branch waveguides, making the platform especially useful for high-power applications.

The risk of COD is high in tree array QCLS from which radiation is emitted from a single output waveguide 136 because radiation from multiple input waveguides 134 is being combined into a single waveguide, creating a region of very high optical intensity. Employing a waveguide coupler 130 that decreases the optical intensity at the output waveguide 136 by expanding the transverse width of the transverse optical mode is an effective way to mitigate or prevent COD without substantially reducing output power. By reducing the optical intensity at the location where it is highest, the total optical power generated in the tree array QCL 142 can be increased without increasing the risk of COD, enabling the tree array QCLs 142 to have higher output power and improved reliability.

Employing a waveguide coupler 130 that expands the transverse optical mode may also be advantageous because it allows narrower input waveguides 134 to be used at the input end 132 of the coupler 130.

The input waveguides 134 to a waveguide coupler 130 in a tree array QCL 142 are typically bent, such as in an S-bend. It may be advantageous for the bent input waveguides 134 to be narrow because narrow waveguides support fewer high order transverse modes, which can be excited in waveguide bends. It is usually undesirable for high order modes to be excited in a tree array QCL because high order modes often increase optical losses and reduce the quality of the emitted laser beam. The input waveguides 134 to the waveguide coupler 136 are close together, so it is advantageous for these waveguides to be narrow to mitigate thermal cross-talk or overheating as narrow waveguides generate less heat than wide waveguides when electrically powered. The mode expanding waveguide coupler 130 allows narrow input waveguides 134 to be combined with wider output waveguides 136, combining the benefits of narrow input waveguides 134 with reduced risk of COD.

In a tree array QCL 142, when the waveguide coupler 130 is a mode compressing coupler (Wi>Wo), the transverse optical modes 138 of the input waveguides 134 are larger in transverse width than the transverse optical mode(s) 140 of the output waveguides 136. The decrease in the transverse width of the transverse optical mode 138 is useful for reducing the ellipticity of the emitted beam. A beam with reduced ellipticity may be collimated with fewer lenses than a highly elliptical beam from a wide waveguide. This allows wide waveguides to be used in the array for high power or other advantages with reduced ellipticity in the emitted beam. The emitted beam may then be collimated with a single lens.

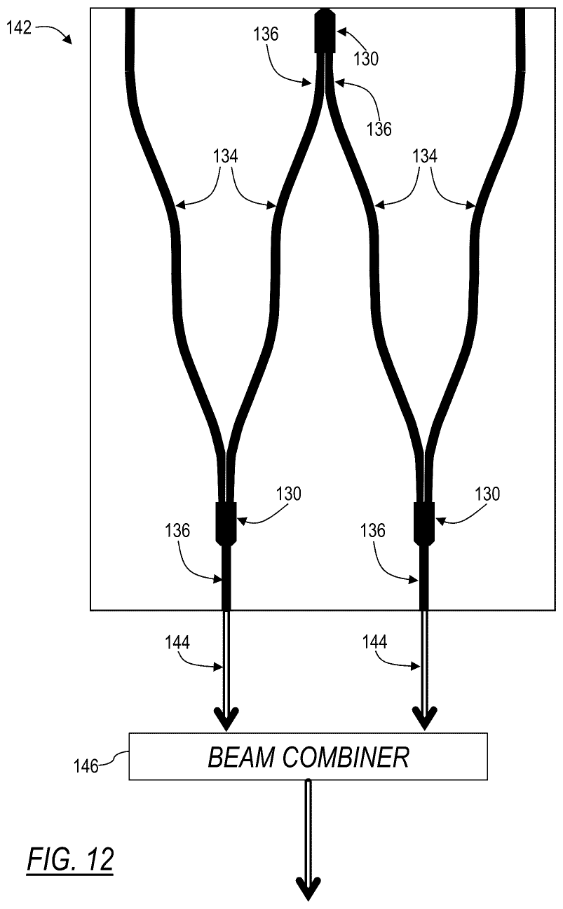

Referring to FIG. 12, an example of a tree array QCL 142 with two layers is shown. A plurality of output waveguides 136 are located at the same edge of the laser chip, from which a beam 144 is emitted. The waveguide couplers 130 are interconnected via input waveguides 134 and output waveguides 136, forming a coherent array. The tree array QCL 142 may have any number of waveguide couplers 130 coupling any number of input waveguides 134 and output waveguides 136.

The interconnections of waveguides within the array allow coupling of the transverse optical modes within the array. The coupling of the transverse optical modes within the array enables coherent emission from the emitter output waveguides 136. The coherence of the light emitted from the plurality of emitter output waveguides 136 is suitable for external coherent beam combining with a beam combiner 146. For example, coherent beam combining by multiplane light conversion may be employed.

The waveguide couplers 130 adjacent to the emitter output waveguides 136 couple multiple input waveguides 134 to a single emitter output waveguide 136. The transverse optical mode(s) 138 of the input waveguides 134 are smaller in transverse width than the transverse optical mode(s) 140 of the output waveguides 136 (Wi<Wo). By increasing the transverse width of the transverse optical mode 138, the fill factor of the emitted light from the edge of the laser array is increased. Increasing the fill factor facilitates external coherent beam combining.

The tree array QCL 142 may also be used as an optical amplifier that receives radiation from another QCL that outputs its beam into the back facet 118 of the QCL array 142. The back facet 118 has an antireflective coating and serves as an input facet for the optical amplifier QCL. The radiation from the external QCL is amplified by the tree array QCL 142 as explained above.

In the tree array QCL 142, the input waveguides 134, waveguide couplers 130, and output waveguides 136 may be powered or unpowered and/or may be implanted with ions to reduce optical absorption by free carriers.

A person having ordinary skill in the art will understand that the QCL, its features, and related methods may be modified in many different ways without departing from the scope of what is claimed. The scope of the claims is not limited to only the particular features and examples described above.

That which is claimed is:

1. A quantum cascade laser (QCL) comprising:
an input ridge waveguide that propagates a transverse optical mode of electromagnetic radiation generated by the QCL;
a multimode interference (MMI) coupler having an input end that receives the transverse optical mode from the input ridge waveguide, modifies a transverse width of the transverse optical mode, and outputs a modified-width transverse optical mode from an output end of the MMI coupler; and
an output ridge waveguide that receives the modified-width transverse optical mode from the output end and propagates the modified-width transverse optical mode;
wherein the input ridge waveguide has a different ridge width than the output ridge waveguide.

2. The QCL of claim 1, wherein the input ridge waveguide has a larger ridge width than the output ridge waveguide and the MMI coupler compresses the transverse width of the transverse optical mode.

3. The QCL of claim 1, wherein the input ridge waveguide has a smaller ridge width than the output ridge waveguide and the MMI coupler expands the transverse width of the transverse optical mode.

4. The QCL of claim 1, wherein the MMI coupler includes a tapered ridge width between the input end and the output end and the tapered ridge width modifies the transverse width of the transverse optical mode.

5. The QCL of claim 1, wherein the QCL is a tree array QCL and the MMI coupler receives the transverse optical mode from more than one input ridge waveguide.

6. The QCL of claim 1, wherein the input ridge waveguide, MMI coupler, and output ridge waveguide together form a monolithic ridge.

7. The QCL of claim 1, wherein the transverse optical mode is TM₀₀ of the input ridge waveguide and the modified-width transverse optical mode is TM₀₀ of the output ridge waveguide.

8. A quantum cascade laser (QCL) comprising:
an input waveguide that propagates a transverse optical mode of electromagnetic radiation generated by the QCL;
a multimode interference (MMI) coupler having (a) an input end that receives the transverse optical mode from the input waveguide, (b) a tapered section that modifies a transverse width of the transverse optical mode, and (c) an output end that outputs a modified-width transverse optical mode; and
an output waveguide that receives the modified-width transverse optical mode from the output end and propagates the modified-width transverse optical mode.

9. The QCL of claim 8, wherein the input waveguide has a larger ridge width than the output waveguide and the tapered section compresses the transverse width of the transverse optical mode.

10. The QCL of claim 8, wherein the input waveguide has a smaller ridge width than the output waveguide and the tapered section expands the transverse width of the transverse optical mode.

11. The QCL of claim 8, wherein the tapered section has a tapered ridge width between the input end and the output end and the tapered ridge width modifies the transverse width of the transverse optical mode.

12. The QCL of claim 8, wherein the MMI coupler reduces an optical intensity of the electromagnetic radiation in the output waveguide relative to the input waveguide.

13. The QCL of claim 8, wherein the input waveguide, MMI coupler, and output waveguide together form a monolithic ridge.

14. The QCL of claim 8, wherein the transverse optical mode is TM₀₀ of the input waveguide and the modified-width transverse optical mode is TM₀₀ of the output waveguide.

15. A tree array quantum cascade laser (QCL) comprising:
a plurality of input waveguides that respectively propagate a transverse optical mode of electromagnetic radiation generated by the QCL;
a multimode interference (MMI) coupler having (a) an input end that receives the transverse optical mode from the plurality of input waveguides, (b) a tapered section that modifies a transverse width of the transverse optical mode, and (c) an output end that outputs a modified-width transverse optical mode; and
a single output waveguide that receives the modified-width transverse optical mode from the output end and propagates the modified-width transverse optical mode.

16. The tree array QCL of claim 15, wherein the input waveguides have a larger ridge width than the output waveguide and the tapered section compresses the transverse width of the transverse optical mode.

17. The tree array QCL of claim 15, wherein the input waveguides have a smaller ridge width than the output waveguide and the tapered section expands the transverse width of the transverse optical mode.

18. The tree array QCL of claim 15, wherein the tapered section has a tapered ridge width between the input end and the output end and the tapered ridge width modifies the transverse width of the transverse optical mode.

19. The tree array QCL of claim 15, wherein the MMI coupler is configured to reduce an optical intensity of the electromagnetic radiation in the output waveguide relative to the input waveguides by expanding the transverse width of the optical mode.

20. The tree array QCL of claim 15, wherein the MMI coupler is configured to reduce an ellipticity of the electromagnetic radiation emitted from the output waveguide relative to the input waveguides by compressing the transverse width of the transverse optical mode.

21. The tree array QCL of claim 15, wherein the input waveguides, MMI coupler, and output waveguide together form a monolithic QCL with a continuous ridge forming the input waveguides, MMI coupler, and output waveguide.

22. The tree array QCL of claim 15, wherein the transverse optical mode is TM₀₀ of the input waveguide and the modified-width transverse optical mode is TM₀₀ of the output waveguide.
